(19) United States
(12) Patent Application Publication
(10) Pub. No.: US 2015/0255685 A1
(43) Pub. Date: Sep. 10, 2015

(54) METHOD FOR PRODUCING AN OPTOELECTRONIC COMPONENT

(71) Applicant: OSRAM OPTO SEMICONDUCTORS GMBH, Regensburg (DE)

(72) Inventors: Siegfried Herrmann, Neukirchen (DE); Norwin Von Malm, Nittendorf (DE)

(21) Appl. No.: 14/430,893

(22) PCT Filed: Sep. 25, 2013
(86) PCT No.: PCT/EP2013/069966

§ 371 Date: Mar. 24, 2015

(30) Foreign Application Priority Data
Sep. 27, 2012 (DE) 10 2012 217 533.4

(51) Int. Cl. H01L 33/46; H01L 33/62; H01L 33/00; H01L 33/38

(52) U.S. Cl. CPC H01L 33/46; H01L 33/382; H01L 33/62; H01L 33/0062; H01L 33/0079; H01L 2933/0016; H01L 2933/0025; H01L 2933/0066

(57) ABSTRACT

The invention relates to an optoelectronic component and a method for producing an optoelectronic component, wherein a layer structure having a positively doped semiconductor layer (2 or 3) and a negatively doped semiconductor layer (3 or 2) with an active zone for generating light, and a mirror layer (4) is grown on a growth substrate, wherein the layer structure is fixed on a first side of a carrier (10) by means of a connecting layer (8) and wherein electrical contacts for the layer structure are introduced via a second side of the carrier (10) and the growth substrate is removed.

The invention relates to a method according to patent claim 1 and to a component according to a further independent patent claim.

DE 10 2010 025 320 A1 discloses an optoelectronic component and a method for producing same.

In the method described, an optically active layer is grown on a growth substrate. The optically active layer is subsequently patterned from the free side, electrical contacts being introduced. The electrical contacts are connected to a positively doped layer and to a negatively doped layer. After the conclusion of the patterning, the component is fixed on a carrier. The growth substrate is subsequently removed.

The object of the invention is to provide an improved method for producing the component and a component constructed in a simple manner.

The object of the invention is achieved by means of the method according to patent claim 1 and by means of the component according to a further independent patent claim.

One advantage of the method described and of the component described is that the carrier is integrated into the component. This obviates the need for the work steps additionally required for carrier production, such as, for example, forming vias, filling vias, bonding pads on the front side, and so on.

Moreover, the integration of the carrier into the optoelectronic component enables both the structure of the carrier and the size of the carrier to be optimally adapted to the component.

Further advantageous embodiments of the method and of the component are specified in the dependent claims.

In one embodiment, the connection layer used is an electrically insulating material, in particular an adhesive material. The use of the electrically insulating material as the connection layer affords the advantage that electrically conducting materials or semiconducting materials can also be used as the carrier. In particular, the use of an adhesive material affords the possibility of enabling a secure and fixed connection between the layer structure and the carrier at small layer thickness. Moreover, a saving of costs can be achieved by the use of adhesive material.

In a further embodiment, the carrier used is an electrically semiconducting or electrically conducting material, in particular in the form of a film. The use of an electrically semiconducting or of an electrically conducting material as the carrier, in particular in the form of a film, affords the advantage that processing is possible in a simple manner. Moreover, it is possible to form thin carriers that constitute a sufficient stability for the optoelectronic component. Particularly with the use of thin carriers, the introduction of the cutout in the carrier for forming the contacts can be carried out rapidly. Consequently, process time and hence costs are saved.

In a further embodiment, the contacts are formed in each case or jointly in a common method step. The contacts in particular in each case fill a cutout completely, wherein the cutout extends through the carrier and in particular additionally through a semiconductor layer. A contact for electrically contacting a semiconductor layer can be embodied in a continuous fashion, for instance between the carrier and the semiconductor layer to be contacted, inclusive. That means that the contact is embodied seamlessly and has no connection layers, for instance a solder layer or an adhesive layer. In particular, the contact only comprises an electrically conductive material, which can be for example a metal or a metal alloy. By way of example, the contact is produced integrally in one method step.

In a further embodiment, for improving the reflective properties, the electrical contacts are provided with a mirror layer.

In a further embodiment, for improving the reflective properties of the component on the side of the carrier a connection material is used which is substantially transmissive to the light emitted by the component. Moreover, a carrier is used whose side is formed in a manner facing the connection layer and in a specularly reflective fashion. Light which is emitted by the active zone in the direction of the carrier is thus reflected from the specularly reflective side of the carrier. Consequently, the light flux emitted via the emission side is increased.

In a further embodiment, the first contact is embodied in such a way that the first contact is embodied in a specularly reflective fashion at a side facing the negatively doped semiconductor layer. By this means, too, the reflection of the emitted light in the direction of the emission side is increased.

In a further embodiment, a filling material having inhomogeneities is used, wherein the filling material comprises a photosensitive material, for example. Simple processing can be achieved in this way. Moreover, the filling material can be removed rapidly and simply by means of a DRIE process, for example, for the purpose of introducing a contact.

By way of example, it is possible to produce the cutouts in the connection layer by laser ablation, wherein an opening in the carrier can function in this case as an aperture. By this means, too, rapid and simple processing is possible.

The above-described properties, features and advantages of this invention and the way in which they are achieved will become clearer and more clearly understood in association with the following description of the exemplary embodiments which are explained in greater detail in association with the drawings, wherein

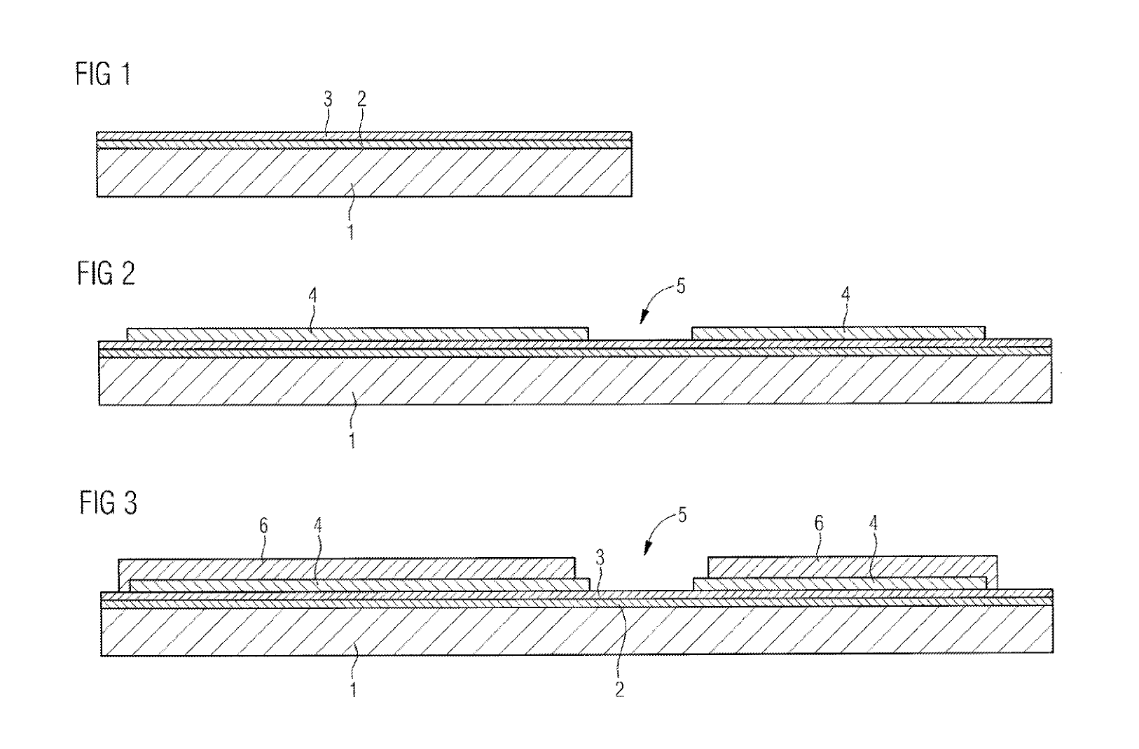

FIGS. 1 to 3 show a first method section,

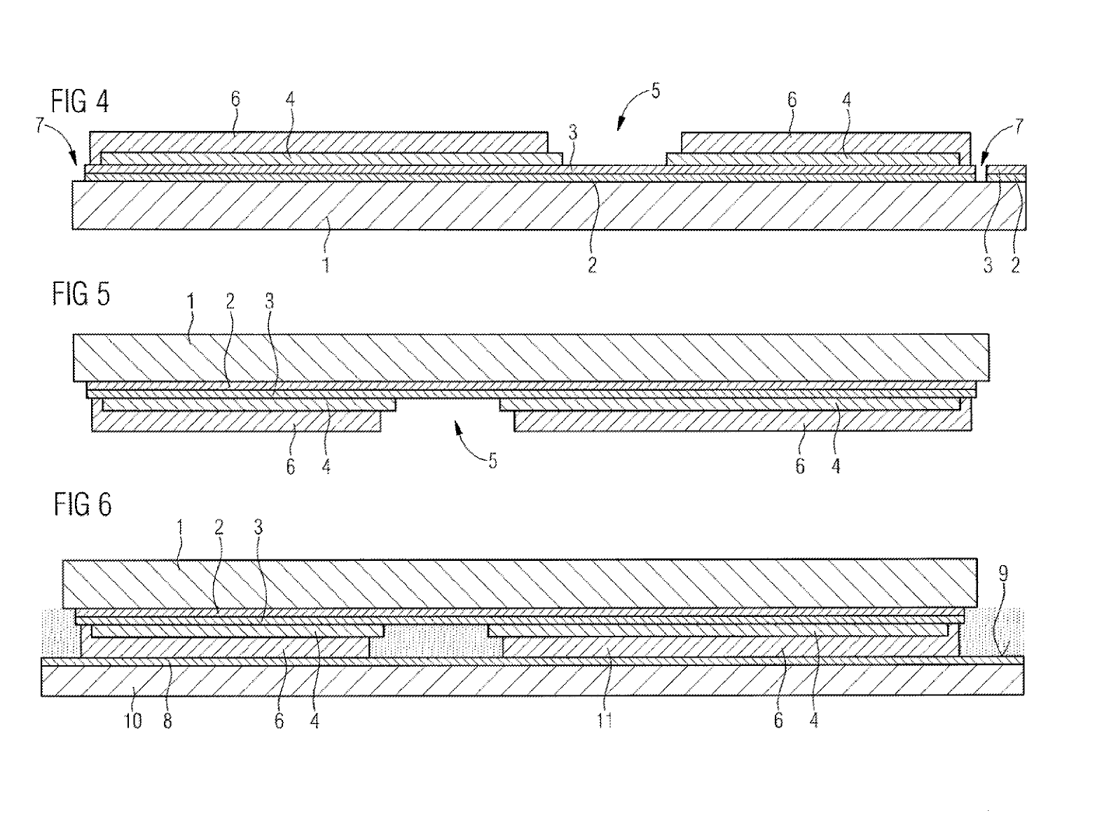

FIG. 4 shows a second method section,

FIGS. 5 and 6 show a third method section,

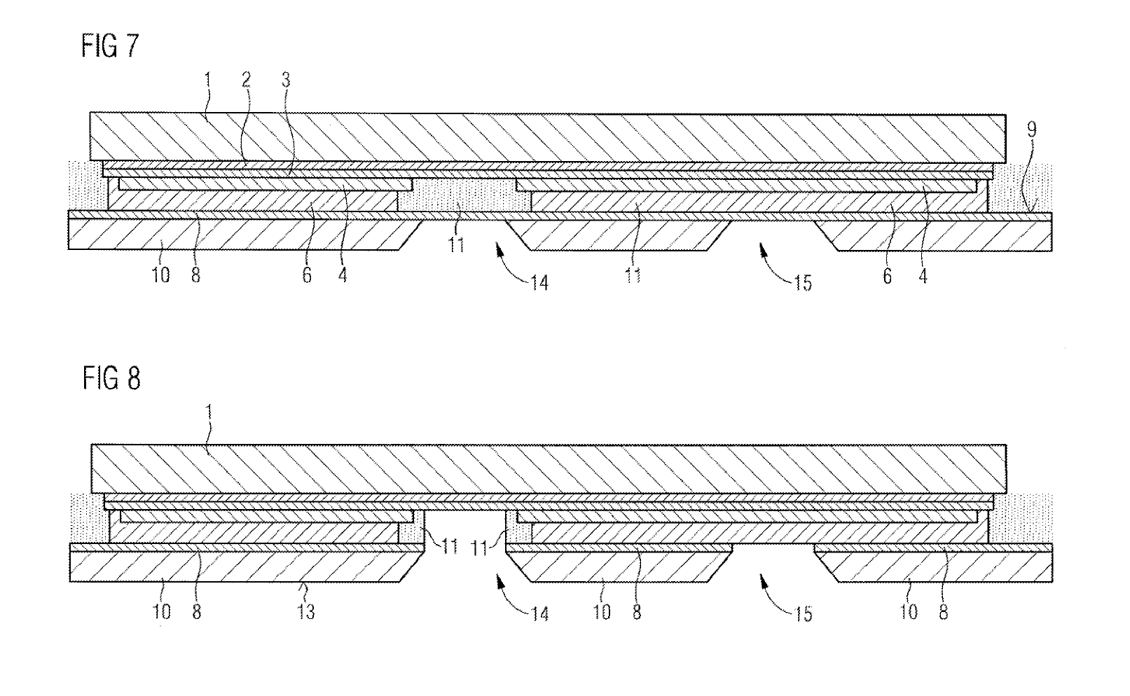

FIGS. 7 and 8 show a fourth method section,

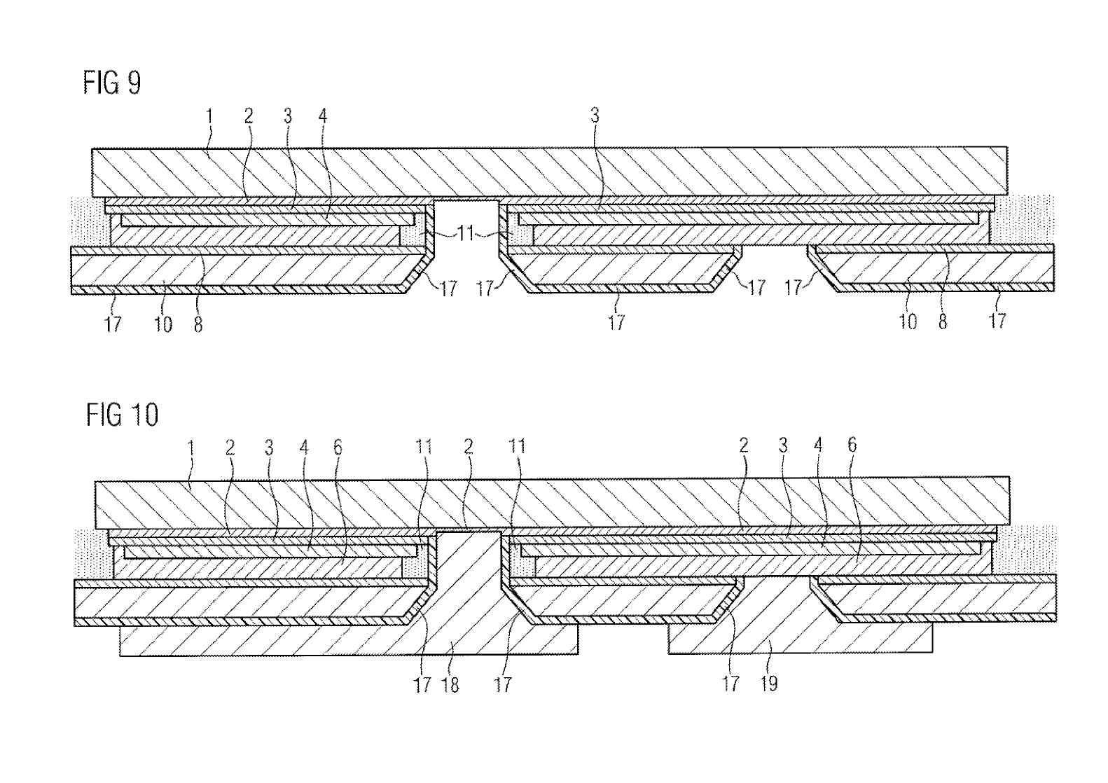

FIGS. 9 and 10 show a fifth method section,

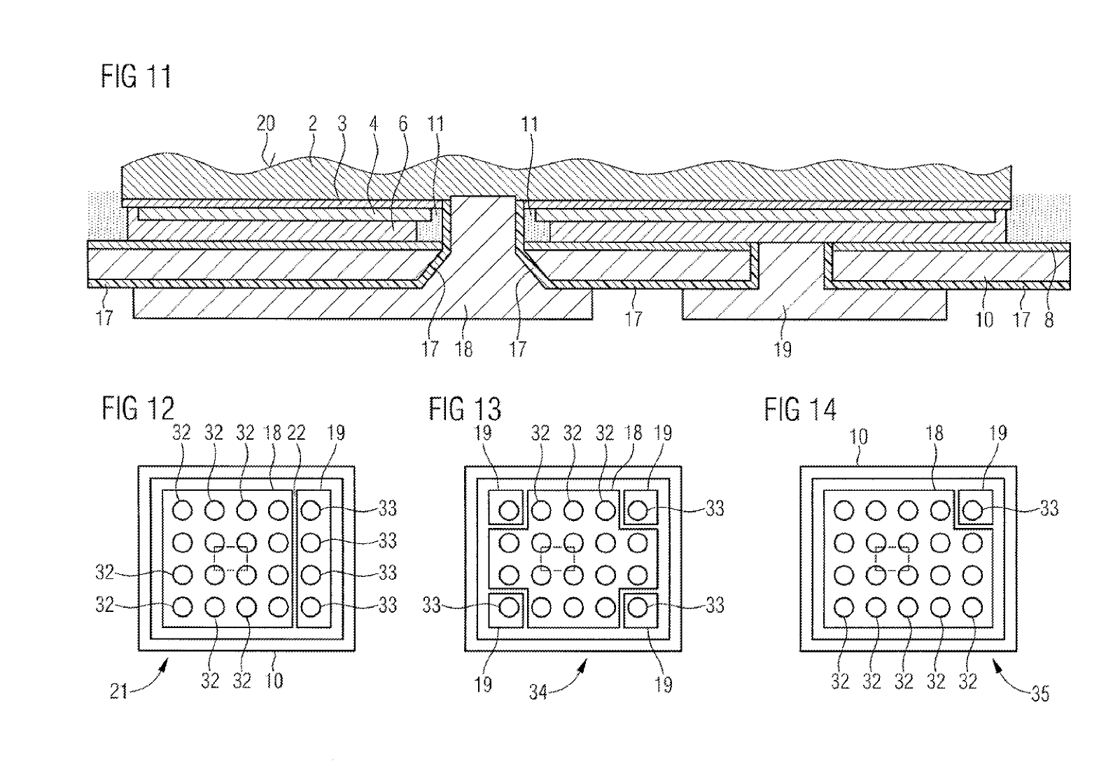

FIG. 11 shows a sixth method section,

FIG. 12 shows a view looking at the carrier of a first embodiment in accordance with FIG. 11,

FIG. 13 shows a view looking at the carrier of a second embodiment in accordance with the sixth method section,

FIG. 14 shows a view of a carrier in accordance with a third embodiment,

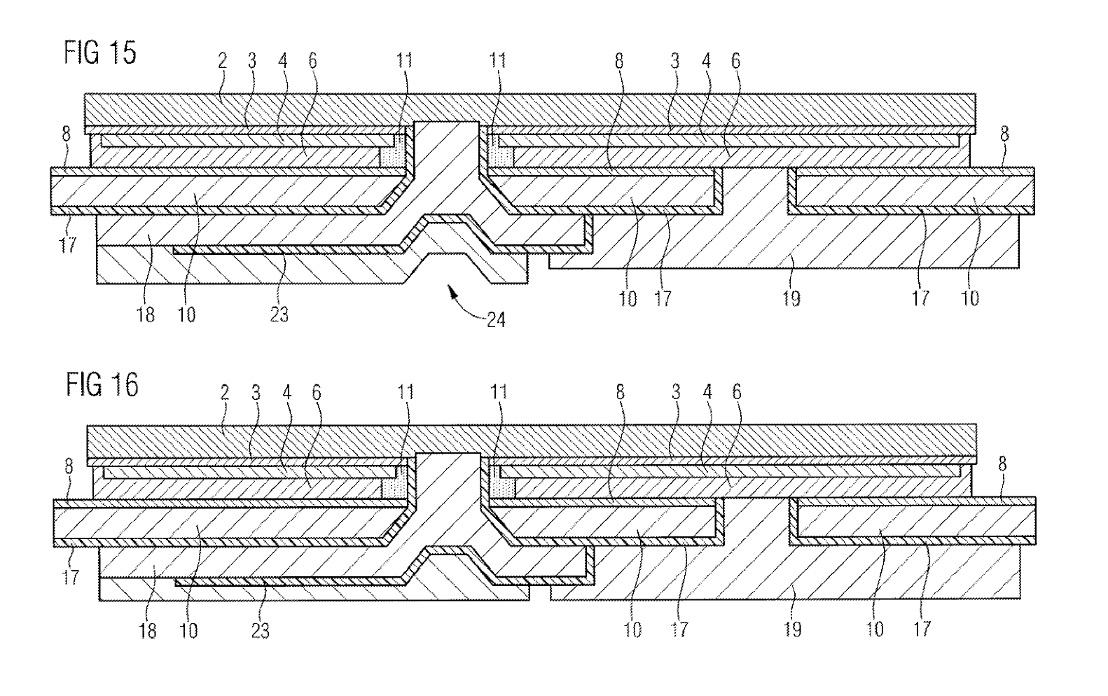

FIGS. 15 to 17 show a fourth process section,

FIG. 18 shows a thinned wafer,

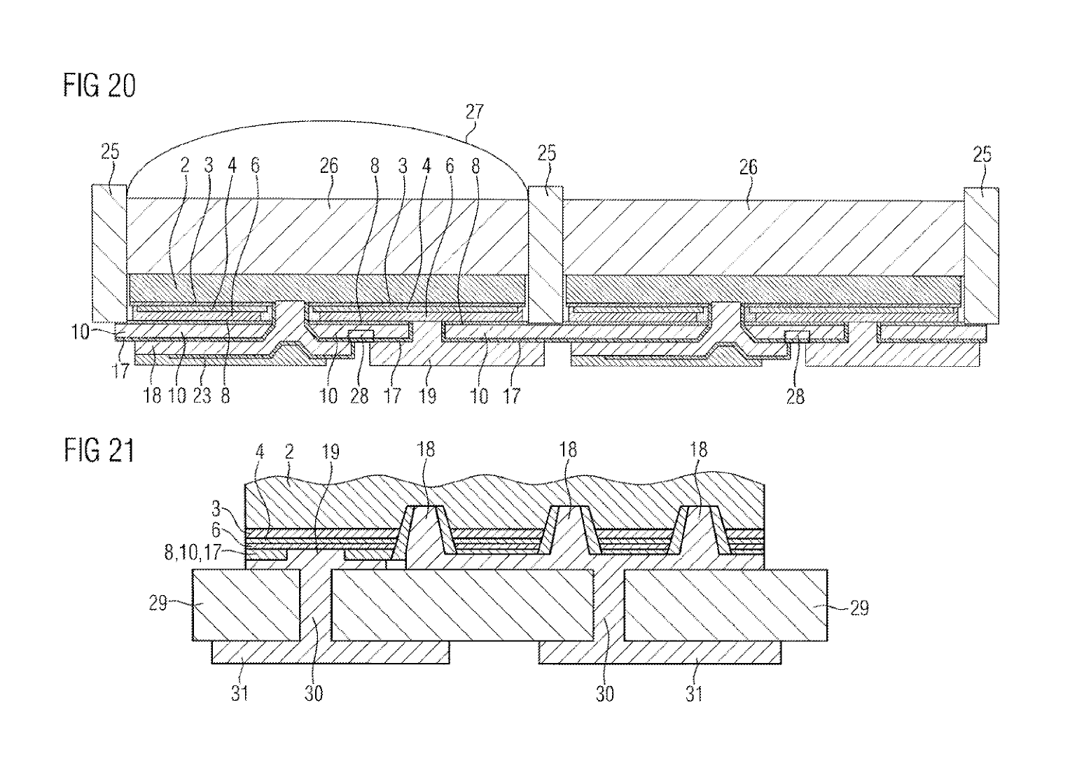

FIG. 19 shows a schematic illustration of an optical component with the use of a thinned wafer as carrier,

FIG. 20 shows components with converter and lens,

And FIG. 21 shows a component with a carrier structure.

FIG. 1 shows a first method step, wherein a negatively doped semiconductor layer 2 is grown onto a growth substrate 1. A positively doped semiconductor layer 3 is grown onto the negatively doped semiconductor layer 2. An active zone is provided at an interface between the negatively doped semiconductor layer 2 and the positively doped semiconductor layer 3, said active zone being designed to generate light. The negatively doped semiconductor layer 2 is designated hereinafter as the first semiconductor layer 2 and the positively doped semiconductor layer 3 is designated hereinafter as the second semiconductor layer 3. Alternatively, the first semiconductor layer 2 can also be p-doped and the second semiconductor layer can be n-doped. The first and second semiconductor layers 2, 3 form e.g. a thin-film diode. The first and second semiconductor layers 2, 3 form a layer structure.

The growth substrate 1 can be embodied for example in the form of sapphire or crystalline silicon. Moreover, the growth substrate 1 can be constructed from silicon carbide or from gallium nitride. The first and second semiconductor layers 2, 3 are grown epitaxially on the growth substrate 1. Depending on the embodiment chosen, an intermediate layer can be applied on the growth substrate 1, said intermediate layer having substantially the same lattice structure as the layer structure to be grown. Growth of the first semiconductor layer 2 can be improved in this way, such that fewer or no defects are produced in the lattice structure of the first semiconductor layer during growth.

Subsequently, as is illustrated in FIG. 2, a mirror layer 4 is applied on the second semiconductor layer 3. The mirror layer 4 can contain a metal such as silver and/or titanium having a high reflection coefficient. Moreover, an opening 5 is provided in the mirror layer 4, such that after the application of the mirror layer 4, in the region of the opening 5, a surface of the positively doped semiconductor layer 3 is exposed, as is illustrated in FIG. 2. The opening 5 can be provided at the same time as the application of the mirror layer 4 or can be introduced subsequently into the mirror layer 4. In a subsequent method step, illustrated in FIG. 3, an electrically conductive layer 6 is applied on the mirror layer 4. Depending on the embodiment chosen, the conductive layer 6 can also be dispensed with. The conductive layer 6 has the opening 5 just like the mirror layer 4. Said opening can be produced separately or together with the opening in the mirror layer 4. As a result, the opening 5 in the two layers 4 and 6 can have the same or different cutouts.

The first and second semiconductor layers 2, 3 can be embodied as an epitaxial layer sequence, that is to say as an epitaxially grown layer structure. In this case, the semiconductor layers 2, 3 can be embodied on the basis of InGaAlN, for example. InGaAlN-based layer structures include, in particular, those in which the epitaxially produced layer structure generally comprises a layer sequence composed of different individual layers which contains at least one individual layer comprising a material from the III-V compound semiconductor material system InxAlyGa1-x-yN where 0<=x<=1, 0<=y<=1 and x+y<=1. The layer structure comprising at least one active layer or an active region on the basis of InGaAlN can for example preferably emit electromagnetic radiation in an ultraviolet to green wavelength range.

Alternatively or additionally, the semiconductor layers 2, 3 or the semiconductor chip can also be based on InGaAlP, that is to say that the layer structure can comprise different individual layers, at least one individual layer of which comprises a material from the III-V compound semiconductor material system InxAlyGa1-x-yP where 0<=x<=1, 0<=y<=1 and x+y<=1. The layer structure, which comprises at least one active layer or an active region on the basis of InGaAlP, can for example preferably emit electromagnetic radiation having one or more spectral components in a green to red wavelength range.

Alternatively or additionally, the semiconductor layers 2, 3 can also comprise other III-V compound semiconductor material systems, for example an AlGaAs-based material, or II-VI compound semiconductor material systems. In particular, an active layer comprising an AlGaAs-based material can be suitable for emitting electromagnetic radiation having one or more spectral components in a red to infrared wavelength range.

A II-VI compound semiconductor material system can comprise at least one element from the second main group, such as Be, Mg, Ca, Sr for example, and an element from the sixth main group, such as O, S, Se, for example. In particular, a II-VI compound semiconductor material system comprises a binary, ternary or quaternary compound comprising at least one element from the second main group and at least one element from the sixth main group. Such a binary, ternary or quaternary compound can moreover comprise for example one or a plurality of dopants and additional constituents. By way of example, the II-VI compound semiconductor materials include ZnSe, ZnTe, ZnO, ZnMgO, ZnS, CdS, ZnCdS, MgBeO.

In this case, the growth substrate 1 can comprise a semiconductor material, for example a compound semiconductor material system mentioned above. In particular, the growth substrate 1 can comprise sapphire, GaAs, GaP, GaN, InP, SiC, Si and/or Ge or can be composed of such a material.

The semiconductor layers 2, 3 can have as active region for example a conventional pn junction, a double heterostructure, a single quantum well structure (SQW structure) or a multi quantum well structure (MQW structure). In the context of the application, the designation quantum well structure encompasses in particular any structure in which charge carriers can experience a quantization of their energy states as a result of confinement. In particular, the designation quantum well structure does not include an indication about the dimensionality of the quantization. It therefore encompasses inter alia quantum wells, quantum wires and quantum dots and any combination of these structures. In addition to the active region, the semiconductor layers 2, 3 can comprise further functional layers and functional regions, for instance p- or n-doped charge carrier transport layers, that is to say electron or hole transport layers, undoped or p- or n-doped confinement, cladding or waveguide layers, barrier layers, planarization layers, buffer layers, protective layers, contact layers and/or electrodes and combinations thereof. Such structures relating to the active region or the further functional layers and regions are known to the person skilled in the art in particular with regard to construction, function and structure and, therefore, will not be explained in greater detail at this juncture.

In a subsequent method step, illustrated in FIG. 4, a trench 7 is introduced into the first and second semiconductor layers 2, 3, said trench separating a part of the layer structure consisting of the first and second semiconductor layers 2, 3 from the remaining part of the layer structure. The trench 7 is formed circumferentially around a part of the layer structure 2, 3 and led as far as the growth substrate 1.

Depending on the embodiment chosen, the method steps in FIGS. 1 to 3 are performed on a larger area of a growth substrate 1, wherein simultaneously in the method steps in FIGS. 2 and 3 for a plurality of optoelectronic components corresponding mutually separate mirror layers 4 and conductive layers 6 are applied to the large-area first and second semiconductor layers 2, 3. In the method step in accordance with FIG. 4, regions of the large-area layer structure are patterned into individual partial regions for a respective component.

FIG. 5 shows the arrangement from FIG. 4, the arrangement having been turned around. The arrangement in accordance with FIG. 5 is fixed onto a top side 9 of a carrier 10 by means of a connection layer 8. The material of the connection layer is also filled into the region of the opening 5. Depending on the embodiment chosen, the opening 5 can be filled with a further filling material 11. In FIGS. 6 and 7, the filling material 11 completely fills the opening 5. In this case, the filling material adjoins the second semiconductor layer 3, the conductive layer 6 and the mirror layer 4. In order to form the first cutout 14, the filling material 11 and the second semiconductor layer 3 are removed regionally, such that the first semiconductor layer 2 is exposed regionally in the first cutout 14. In particular, the remaining filling material 11 surrounds the first cutout 14 in a lateral direction. In this case, the remaining filling material 11 is arranged between the first cutout 14 and the mirror layer 4 in the lateral direction. The filling material 11 can be embodied in a reflective fashion. By way of example, the filling material contains particles for increasing the reflectivity, for instance titanium oxide particles. With the aid of the connection layer 8, the first and second semiconductor layers 2, 3 with the mirror layer 4 and the conductive layer 6 are fixed at the top side 9 of the carrier 10. In one embodiment, use is made of a filling material 11 having inhomogeneities, for example voids and/or fillers and/or scattering particles. Moreover, the filling material 11 can be embodied as photosensitive material, for example. Simple processing can be achieved in this way.

The connection layer 8 can be formed from an adhesive material, for example can be embodied as an electrically nonconductive adhesive. In a further embodiment, the connection layer 8 can also be embodied in the form of an electrically conductive material, for example composed of metal, which fixes the semiconductor layers 2, 3 at the top side 9 of the carrier 10 by means of a soldering connection.

The following materials are suitable for the embodiment of the connection layer in the form of an adhesive: thermoplastics (e.g. Brewer Science Waferbond), two-component polyurethanes (DELO-PUR 9604), two-component epoxy resins (di- or polyepoxides on the basis of bisphenol A, novolacs, etc., curing agents polyamines, mercaptans), polyimides (Adhesives HD 3007/HD 7010 Dupont/HD Microsystems) acrylates, silicones (dimethylsilicone).

The adhesive-bonding process in accordance with FIG. 6 is carried out in a membrane bonder, for example. Depending on the embodiment chosen, it is possible to achieve layer thicknesses for the connection layer 8 in the range of less than 10 μm between the top side of the carrier 10 and the free top side of the free mirror layer or the free top side of the conductive layer 6. The thickness of the connection layer 8 can for example also be less than 1 μm.

With the use of a non-electrically conducting connection layer 8, it is also possible to use electrically conducting materials such as, for example, metals (Mo, W, C, CuW, AlSi, AlSiC) or electrically semiconducting materials such as, for example, Si, Ge, GaAs as the carrier 10. The carrier 10 can also be embodied in the form of a film, wherein the layer thicknesses can be for example in the range of 100 μm but also smaller down to the range of 10 μm. In the case of the embodiment of the carrier 10 composed of a metal, the carrier can be provided with an electrical insulation layer by means of an ALD, CVD or PVD process, for example. The carrier 10 can also be embodied in the form of an electrically insulating layer, in particular in the form of a film, for example in the form of a plastic film.

Furthermore, before the adhesive-bonding process, the opening 5 can be filled with a filling material 11. A suitable filling material 11 is for example a photosensitive material (ProTEK) or a coating which can be removed again by means of a DRIE process.

By providing the carrier 10 in the form of films, in particular in the form of metal films, it is possible to use roll-to-roll production during the connection process in accordance with FIG. 6. Moreover, the connection between the carrier 10 and the semiconductor layers 2, 3 can be reconfigured in a planar, very thin and homogeneous fashion on account of the process sequence. Furthermore, an ESD diode can be integrated directly into the system, for example between the contact pads on an underside of the carrier. In the case of an embodiment of the carrier 10 in the form of silicon, the ESD diode can also be integrated directly into the silicon. This can be carried out by means of a local implantation, wherein the connection is effected by means of a bonding pad metallization or the redistribution wiring planes connected thereto.

With the use of a soldering connection as connection layer on a passivated carrier 10 composed of silicon, the patterning by the trenches 7 (mesa patterning) is carried out after the detachment of the growth substrate 1. The passivation is carried out for example by means of an ALD method after the mirror layer 4 has been etched back.

In a subsequent method step, illustrated in FIG. 7, a first cutout 14 is introduced from an underside 13 of the carrier 10 in the region of the opening 5 of the mirror layer 4. Moreover, a second cutout 15 is introduced in the region of the mirror layer. The first and second cutouts 14, 15 are introduced by corresponding methods depending on the material of the carrier 10. In the case of the embodiment of the carrier 10 in the form of semiconducting material, etching methods can be used, for example. In the case of the embodiment of the carrier 10 in the form of metal, metal-removing methods such as laser ablation, for example, can be used. This method state is illustrated in FIG. 7.

Afterward, in a subsequent method step, the connection layer 8 and, if appropriate, the filling material 11 above the first cutout 14 are removed, such that the cutout 14 adjoins the negatively doped semiconductor layer 2 arranged above the active zone 16. Moreover, the connection layer 8 is removed in the region of the second cutout 15, such that the second cutout 15 is led as far as the conductive layer 6 or, in the absence of the conductive layer 6, as far as the mirror layer 4. This method state is illustrated in FIG. 8.

Depending on the type of the filling material 11 and the connection layer 8, a DRIE process, for example, can be used for removing the connection layer 8 and the filling material 11. Moreover, the filling material 11 and the connection layer 8 can be removed by a laser ablation method, for example. In this case, the first and/or second cutout 14, 15 already provided in the carrier 10 serve(s) as aperture.

In a subsequent method step, illustrated in FIG. 9, an insulation layer 17 is applied to the underside 13 and the side walls of the first and second cutouts 14, 15. Depending on the embodiment chosen, the insulation layer 17 at the side wall of the cutout 14 can be embodied in the form of a mirror layer. After the application of the insulation layer 17 and the patterning thereof, the first cutout 14 still directly adjoins the first semiconductor layer 2. Moreover, the second cutout 15 adjoins the conductive layer 6 or, in the absence of the conductive layer 6, the mirror layer 4. The insulation layer 17 can be deposited for example with the aid of an ALD or a TEOS-based CVD process. In a further embodiment, before the introduction of the electrically conductive material for the production of the first contact, an electrically conductive and specularly reflective metal layer is applied on the free area of the negatively doped semiconductor layer 2 and the free area of the insulation layer 17 in the region of the first cutout 14.

In a subsequent method step, the first and second cutouts 14, 15 are filled with an electrically conductive material, for example with a metal using a plating method, and afterward a first and respectively a second contact pad 18, 19 are applied to an underside of the insulation layer 17. Depending on the embodiment of the carrier 10, a planarization step, for example by means of CMP, can be carried out before or after the application of the contact pads 18, 19. This method state is illustrated in FIG. 10.

A first contact 32 is formed in the first cutout 14. A second contact 33 can be formed in the second cutout 15. The introduction of the first contact 32 or of the second contact 33 can be carried out in one method step, for instance by filling the cutout 14 or 15 with an electrically conductive material in particular using a plating method.

The first contact 32 extends through the carrier 10, the connection layer 8, the mirror layer 4 and the second semiconductor layer 3 into the first semiconductor layer 2. The formation of the first contact 32 for electrically contacting the first semiconductor layer 2 is thus carried out simultaneously in the carrier 10 and in the second semiconductor layer 3. Within the first cutout 14, the first contact 32 is formed continuously, in particular, between the first semiconductor layer 2 and the first contact pad 18. That means that the first contact 32 within the first cutout is formed approximately integrally between the first semiconductor layer 2 and the first contact pad 18. By way of example, the first contact 32 comprises only an electrically conductive material which is used in a method step for filling the first cutout 14 between the first semiconductor layer 2 and the first contact pad 18. In particular, the contact 32 is free of a connection layer which connects a first part of the contact 32, said first part being laterally surrounded by the carrier 10, to a further part of the contact 32, said further part being laterally surrounded by the second semiconductor layer 3, wherein the connection layer comprises a different material than the first part or the further part of the contact 32.

The second contact 33 extends through the carrier 10 and the connection layer 8. Within the second cutout 15, the second contact 33 is formed continuously, in particular. By way of example, the second contact 33 comprises only an electrically conductive material which is used in a method step for filling the second cutout 15. In FIG. 10, the second contact 33 is electrically connected to the second semiconductor layer 3 by means of the mirror layer 4 and the conductive layer 6. In a departure therefrom, the second contact 33 can also be directly in electrical contact with the second semiconductor layer 3.

Moreover, with the use of a carrier composed of a semiconducting material, for example in the form of a silicon wafer, the insulation layer 17 can be embodied as a silicon dioxide layer.

The growth substrate 1 is subsequently removed. For this purpose, the growth substrate 1 can be lifted off by a laser lift-off method or removed by a CMP method, for example. Afterward, an upper side surface 20 of the first semiconductor layer 2 is roughened. This method state is illustrated in FIG. 11, wherein the thickness of the first semiconductor layer 2 is illustrated in an enlarged manner. Moreover, the individual components are singulated.

FIG. 12 shows a first component 21 with a plan view of the first and second contact pad 18, 19. The first and second contact pads 18, 19 are electrically isolated by a second trench 22. Moreover, a plurality of first and second cutouts 14, 15 are provided in the embodiment illustrated, which cutouts are filled with electrically conductive material and constitute the first and second electrical contacts 32, 33, respectively. The first electrical contacts for the negatively doped semiconductor layer 2 are arranged in a 4×4 arrangement. The second electrical contacts for the positively doped semiconductor layer 3 are arranged in the form of four second electrical contacts arranged in series.

FIG. 13 shows one embodiment of a second component 34, second contact pads 19 arranged in four corner regions being provided. The second contact pads 19 are separated from the first contact pad 18 in each case by means of a second trench 22. Analogously to the arrangement of the second contact pads 19, the second electrical contacts 33 are also arranged in the corner regions of the square. Analogously to the embodiment of the form of the first contact pad 18, the first electrical contacts 32 are arranged in a manner distributed uniformly over the area of the first contact pad 18.

FIG. 14 shows one embodiment of a third component 35, wherein only one second contact pad 19 is arranged in a corner region, said second contact pad being electrically insulated from the first contact pad 18, which is embodied in a substantially square fashion, by means of a second trench 22. In an analogous manner, provision is also made of only one second electrical contact 33 for contacting the positively doped semiconductor layer 3. Moreover, first electrical contacts 32 are provided in a manner distributed uniformly over the area of the first contact pad 18.

The embodiments illustrated in FIGS. 12 to 14 are merely examples of the possible division of the first and second contact pads 18, 19 and the corresponding first and second electrical contacts 32, 33.

FIG. 15 shows a further embodiment, which is substantially constructed in accordance with FIG. 11, but wherein an additional insulation layer 23 is applied on the first contact pad 18 partly in a region adjoining the second contact pad 19. Furthermore, the second contact pad 19 is formed laterally beyond the additional insulation layer 23. Moreover, the first contact pad 18 is embodied in two layers, wherein the first layer bears on the insulation layer 17 and the second layer bears on the first layer and on the further insulation layer 23. The additional insulation layer 23 has a depression in the region of the first cutout 14, said depression forming as a result of the absence of a planarization process. In an analogous manner, the first contact pad 18 has an indentation 24 in the region of the second layer. Such an indentation can also arise in the region of the cutout 15. The first and second contact pad 18, 19 can subsequently be planarized, such that the structure thereof is obtained in accordance with FIG. 16.

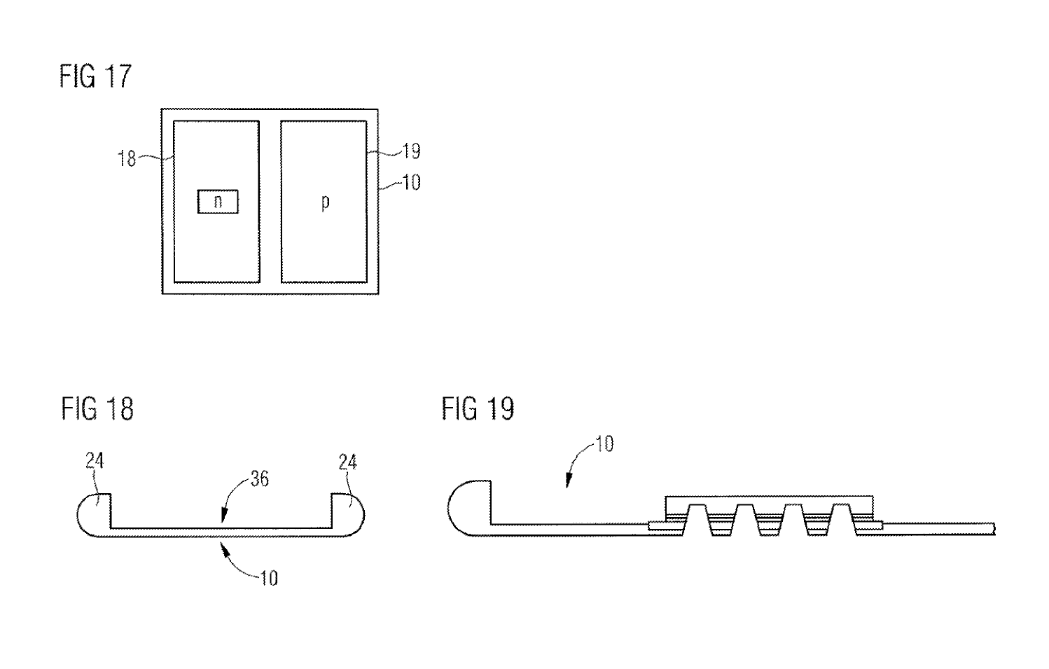

FIG. 17 shows a view of the first and second contact pads 18, 19. The provision of the additional insulation layer 23 makes it possible to fashion the geometry of the first and second contact pad 18, 19 more flexibly and to decouple it from the actual arrangement of the first and second contacts.

FIG. 18 shows a carrier 10 in the form of a semiconductor wafer having an edge 24 extending circumferentially in a ring-shaped fashion with an increased thickness in comparison with a central region 36. By way of example, the wafer is embodied as a silicon wafer. This form of the carrier is achieved by an inner region of the wafer being thinned, wherein a circumferential edge region with a larger thickness remains. This supports the mechanical stability of the wafer. The carrier in accordance with FIG. 18 is produced e.g. by a Taiko method from the company Disco. The thickness of the silicon wafer comprises 10 μm, for example, in the central region 36.

The carrier illustrated in FIG. 18 is used as the carrier 10 in accordance with FIG. 6. Corresponding patterning provisions are subsequently carried out, wherein FIG. 19 illustrates the method state in accordance with FIG. 8. Analogously to the arrangement illustrated in FIG. 19, a multiplicity of components can be processed onto the carrier in accordance with FIG. 19.

FIG. 20 shows a method state in which two components in accordance with FIG. 16 are arranged on a carrier 10, wherein a circumferential separating structure 25 in the form of a frame was applied between the components 21 with the aid of a photoresist, for example. Moreover, a converter layer 26 and a lens 27 were applied into the frame onto the negatively doped semiconductor layer 2.

The separating structure 25 in the form of a frame is produced with the aid of a photoresist process, for example. The frame structure can be produced for example from a plastic, for example benzocyclobutene. The converter layer 26 comprises silicone, for example, into which a luminescent conversion substance, for example YAG: Ce, or other substances is or are embedded.

In FIG. 20, schematically an ESD diode 28 is introduced into the carrier 10 by means of a corresponding doping. Moreover, the ESD diode 28 can also be formed on an underside of the carrier 10, for example between the contact pads 18, 19.

The component illustrated in FIG. 20 can subsequently be applied to a further carrier structure 29 having vias 30 and further contacts 31, as illustrated in a schematic cross section in FIG. 21. The further contacts 31 are arranged on an underside of the carrier structure 29, and the component 21 is arranged on the top side of the carrier structure 29.

The further contacts are arranged on the underside of the carrier structure 29 and connected to corresponding contact pads 18, 19 of the component by means of the vias 30.

Although the invention has been more specifically illustrated and described in detail by means of the preferred exemplary embodiment, nevertheless the invention is not restricted by the examples disclosed, and other variations can be derived therefrom by the person skilled in the art, without departing from the scope of protection of the invention.

This patent application claims the priority of German patent application 10 2012 217 533.4, the disclosure content of which is hereby incorporated by reference.

### LIST OF REFERENCE SIGNS

1 Growth substrate
2 Negatively doped semiconductor layer
3 Positively doped semiconductor layer
4 Mirror layer
5 Opening
6 Conductive layer
7 Trench
8 Connection layer
9 Top side
10 Carrier
11 Filling material
13 Underside
14 1^{st} cutout
15 2^{nd} cutout
16 Active zone
17 Insulation layer
18 1^{st} contact pad
19 2^{nd} contact pad
20 Top side
21 1^{st} component
22 2^{nd} trench
23 Additional insulation layer
24 Edge
25 Separating structure
26 Converter layer
27 Lens
28 ESD diode
29 Carrier structure
30 Via
31 Further contacts
32 1^{st} electrical contact
33 2^{nd} electrical contact
34 2^{nd} component
35 3^{rd} component
36 Central region

1. A method for producing an optoelectronic component,
wherein a layer structure having a first semiconductor layer, a second semiconductor layer, and having an active zone for generating light is grown on a growth substrate, wherein a mirror layer is applied to the first semiconductor layer facing away from the growth substrate, wherein the layer structure is fixed on a first side of a carrier by means of a connection layer, and wherein electrical contacts for the layer structure are introduced via a second side of the carrier, and wherein the growth substrate is removed, and wherein the carrier used is a carrier embodied in a specularly reflective fashion at a side facing the connection layer.

2. The method according to claim 1,
wherein
a first cutout is introduced into the carrier, into the connection layer and into the second semiconductor layer, such that the first cutout adjoins the first semiconductor layer, and
a first contact for electrically contacting the first semiconductor layer is introduced into the cutout.

3. The method according to claim 2,
wherein introducing the first contact is carried out in one method step, such that the first contact extends through the carrier the connection layer and the second semiconductor layer into the first semiconductor layer.

4. The method according to claim 1,
wherein a cutout is introduced into the connection layer, into the carrier and into the second semiconductor layer, wherein the cutout adjoins the first semiconductor layer, wherein a side surface of the cutout is covered with an insulation layer, wherein a first electrical contact for contacting the first semiconductor layer is introduced into the cutout, wherein a second cutout is introduced into the carrier, wherein the second cutout adjoins the mirror layer or an electrically conductive layer covering the mirror layer, wherein a side surface of the second cutout is covered with a further insulation layer, wherein a second electrical contact for contacting a second semiconductor layer is introduced into the second cutout.

5. The method according to claim 4,
a. wherein before the process of introducing the first and/or the second contact, a further mirror layer is applied to the side surface of the first and/or the second cutout,
b. or wherein a connection material that is substantially transmissive to the light emitted by the active zone is used, or
c. wherein the first contact is embodied in such a way that the first contact is embodied in a specularly reflective fashion at a side facing the first semiconductor layer.

6. The method according to claim 4,
wherein a third insulation layer is applied to the carrier, wherein an electrically conductive first contact pad (contact area) is applied to the third insulation layer and is connected to the first contact, and wherein an electrically conductive second contact pad is applied to the third insulation layer and is connected to the second contact, wherein the first and second contact pads are electrically insulated from one another, wherein a fourth insulation layer is applied to the first contact pad, wherein the second contact pad is at least partly applied to the fourth insulation layer.

7. The method according to claim 1, wherein the connection layer is formed from an electrically insulating material, in particular from an adhesive material.

8. The method according to claim 1, wherein the carrier used is an electrically semiconducting or an electrically conducting material, in particular in the form of a film.

9. The method according to claim 1, wherein the growth substrate is removed from a surface of the first semiconductor layer, wherein the exposed surface of the freed first semiconductor layer is roughened.

10. The method according to claim 1, wherein the carrier used is a wafer, in particular a thinned wafer having a thicker edge region.

11. An optoelectronic component, produced in particular according to claim 1, comprising a carrier with a layer structure having a second semiconductor layer and a first semiconductor layer with an active zone for generating light and a mirror layer,
wherein the layer structure is connected to a first side of the carrier via a connection layer, and wherein a first electrical contact and a second electrical contact for contacting the layer structure are provided in the carrier, wherein the contacts are led from the first side to an opposite second side of the carrier, and wherein the connection layer is formed from an electrically insulating material.

12. An optoelectronic component comprising a carrier and a layer structure having a first semiconductor layer, a second semiconductor layer and an active zone for generating light, wherein
the layer structure is connected to a first side of the carrier via a connection layer,
the connection layer is formed from an electrically insulating material,
the component has a first contact and a second contact for electrically contacting the layer structure,
the first contact for electrically contacting the first semiconductor layer extends regionally from a rear side of the carrier through a cutout to the first semiconductor layer,
the cutout is formed in the carrier, in the connection layer and in the second semiconductor layer, and
the first contact is embodied in a continuous fashion within the cutout.

13. The component according to claim 12,
wherein a mirror layer of the component, the connection layer, the second semiconductor layer and the carrier comprise the cutout, wherein the cutout adjoins the first semiconductor layer, wherein the second semiconductor layer is arranged between the first semiconductor layer and the carrier, wherein a side surface of the cutout is covered with an insulation layer, wherein the first electrical contact is arranged in the cutout, wherein a further cutout is introduced in the carrier, wherein the further cutout adjoins the mirror layer or an electrically conductive layer covering the mirror layer, wherein a side surface of the further cutout is covered with an insulation layer, wherein the second electrical contact is arranged in the further cutout.

14. The component according to claim 11, wherein an insulation layer is applied to the carrier, wherein an electrically conductive first contact pad (contact area) is applied to the insulation layer and is connected to the first contact, and wherein an electrically conductive second contact pad is applied to the insulation layer and is connected to the second contact, and wherein the first and the second contact pad are electrically isolated from one another, wherein a further insulation layer is applied to the first contact pad, wherein the second contact pad is also partly applied to the further insulation layer.

15. The component according to claim 11,
wherein the carrier is formed from an electrically semiconducting or electrically conducting material, in particular from metal.

16. The component according to claim 11,
wherein the carrier is embodied in the form of a film composed of metal or a semiconductor material.

17. The component according to claim 11,
wherein the connection layer has a layer thickness of less than 10 μm, in particular less than 1 μm, and wherein the carrier has a layer thickness of less than 100 μm, in particular less than 10 μm.

18. The component according to claim 11,
wherein a connection material that is substantially transmissive to the light emitted by the active zone is provided, and wherein the carrier used is a carrier which is embodied in a specularly reflective fashion at a side facing the connection layer.

19. The component according to claim 12,
wherein the carrier projects laterally in all directions beyond the semiconductor layer structure which is arranged on the connection layer.
